(19) United States
(12) Patent Application Publication
(10) Pub. No.: US 2007/0178822 A1
(43) Pub. Date: Aug. 2, 2007

(54) Method and apparatus for maintaining a cooling air path

(76) Inventors: Mark S. Lanus, Tempe, AZ (US); Wolfgang Poschenrieder, Zorneding (DE)

Correspondence Address: MOTOROLA, INC., LAW DEPARTMENT, 1303 E. ALGONQUIN ROAD, SCHAUMBURG, IL, 60196, US

(21) Appl. No.: 11/344,309

(22) Filed: Jan. 31, 2006

(51) Int. Cl. H05K 5/00

(52) U.S. Cl. 454/184

(57) ABSTRACT

A method of maintaining a cooling air path in an embedded computer chassis having a front side and a rear side includes providing a computing module portion and a fan module portion disposed adjacent to the computing module portion to accept a plurality of fan modules for drawing cooling air though the computing module portion. Cooling air is drawn into the front side of the embedded computer chassis through an air plenum disposed adjacent to the computing module portion, where the cooling air passes through the computing module portion, and where the cooling air is exhausted from the fan module portion through a rear side of the embedded computer chassis, thereby defining the cooling air path. An opening force is applied to a fan module portion cover to place the fan module portion cover in an open position, where the fan module portion cover is rotatable to the open position away and down from the fan module portion, where while in the open position the cooling air path is substantially interrupted. Upon release of the opening force, an elastic means automatically rotates the fan module portion cover to a closed position up and towards the fan module portion, thereby maintaining the cooling air path.

### BACKGROUND OF INVENTION

Embedded computer chassis systems generally include numerous rack-mounted computer cards connected to a backplane. The computer cards may include payload cards and switch module cards that communicate using a bus or switched fabric topology over the backplane. The payload cards and switch cards may be chosen so as to provide the computer chassis with the functionality and features desired by a user.

Each embedded computer chassis generally includes cooling fan modules mounted in the chassis to cool the computer cards. Periodically, these cooling fan modules may need to be removed for maintenance and replacement without interrupting the operation of the embedded computer chassis. Access to the cooling fan modules may require removing a panel or opening a door of the chassis to obtain access. The period of time the chassis may operate with the cooling system out of conformance is known as the service interval. A well-designed computer chassis may have a reasonable service interval designed in so that for the time it takes to replace a failed cooling fan module, the entire chassis is not in danger of overheating. This is contrasted with the Mean Time To Repair (MTTR) for a failed cooling fan module, which is generally lengthy. The Mean Time To Repair is the time after a fan module fails until the repair activity has been completed, including replacing the failed fan module (service interval). The service interval is a very small fraction of this time. The majority of the MTTR is for the service center to become aware of the failure condition, the time to find a qualified technician to work on the equipment, the time to travel to the site, and the time to do preliminary diagnostic work to verify that the fan module needs to be replaced. The MTTR is typically in the range of 4-72 hours. The service interval is the tail end of the MTTR interval consisting of the interval between the time that the failed fan module is removed from the shelf and the time at which the new fan module is inserted into the shelf and the fans are told to spin up to their designated speed. This is typically in the range of 3-15 minutes.

The service interval of the chassis cooling system with a panel removed or an access door open can be very short as the path of the cooling air is disturbed so that short-circuiting of cooling air can occur. This leaves service personnel precious little time to swap out a failed cooling fan module without the chassis overheating.

There is a need, not met in the prior art, for an apparatus and method to maintain the cooling air path in an embedded computer chassis during maintenance of the cooling fan modules. Accordingly, there is a significant need for an apparatus that overcomes the deficiencies of the prior art outlined above.

### BRIEF DESCRIPTION OF THE DRAWINGS

Representative elements, operational features, applications and/or advantages of the present invention reside inter alia in the details of construction and operation as more fully hereafter depicted, described and claimed—reference being made to the accompanying drawings forming a part hereof, wherein like numerals refer to like parts throughout. Other elements, operational features, applications and/or advantages will become apparent in light of certain exemplary embodiments recited in the Detailed Description, wherein:

FIG. 1 representatively illustrates a computer system in accordance with an exemplary embodiment of the present invention;

FIG. 2 representatively illustrates a cut-away elevation view of a computer system in accordance with an exemplary embodiment of the present invention;

FIG. 3 representatively illustrates a cut-away elevation view of a computer system in accordance with another exemplary embodiment of the present invention;

FIG. 4 representatively illustrates a computer system in accordance with another exemplary embodiment of the present invention; and

FIG. 5 representatively illustrates a computer system in accordance with yet another exemplary embodiment of the present invention.

Elements in the Figures are illustrated for simplicity and clarity and have not necessarily been drawn to scale. For example, the dimensions of some of the elements in the Figures may be exaggerated relative to other elements to help improve understanding of various embodiments of the present invention. Furthermore, the terms “first”, “second”, and the like herein, if any, are used inter alia for distinguishing between similar elements and not necessarily for describing a sequential or chronological order. Moreover, the terms “front”, “back”, “top”, “bottom”, “over”, “under”, and the like in the Description and/or in the Claims, if any, are generally employed for descriptive purposes and not necessarily for comprehensively describing exclusive relative position. Any of the preceding terms so used may be interchanged under appropriate circumstances such that various embodiments of the invention described herein may be capable of operation in other configurations and/or orientations than those explicitly illustrated or otherwise described.

### DETAILED DESCRIPTION OF EXEMPLARY EMBODIMENTS

The following representative descriptions of the present invention generally relate to exemplary embodiments and the inventor's conception of the best mode, and are not intended to limit the applicability or configuration of the invention in any way. Rather, the following description is intended to provide convenient illustrations for implementing various embodiments of the invention. As will become apparent, changes may be made in the function and/or arrangement of any of the elements described in the disclosed exemplary embodiments without departing from the spirit and scope of the invention.

For clarity of explanation, the embodiments of the present invention are presented, in part, as comprising individual functional blocks. The functions represented by these blocks may be provided through the use of either shared or dedicated hardware, including, but not limited to, hardware capable of executing software. The present invention is not limited to implementation by any particular set of elements, and the description herein is merely representational of one embodiment.

The terms “a” or “an”, as used herein, are defined as one, or more than one. The term “plurality,” as used herein, is defined as two, or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

A detailed description of an exemplary application is provided as a specific enabling disclosure that may be generalized to any application of the disclosed system, device and method for maintaining a cooling air path in accordance with various embodiments of the present invention.

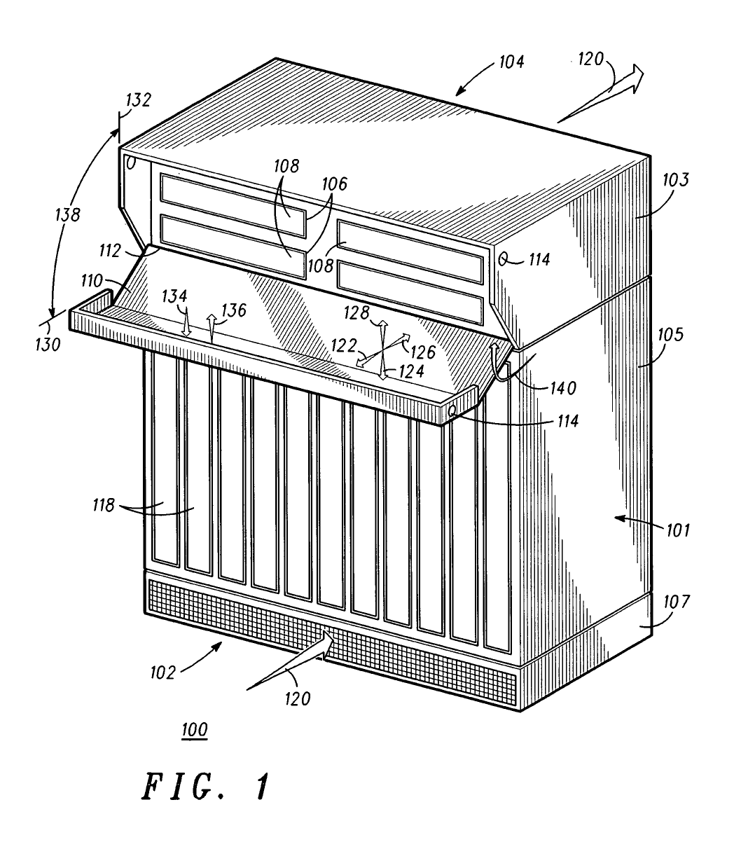

FIG. 1 representatively illustrates a computer system 100 in accordance with an exemplary embodiment of the present invention. Computer system 100 may include an embedded computer chassis 101 having a front side 102 and a rear side 104. In an embodiment, computer system 100 and embedded computer chassis 101 may comply with the Advanced Telecom and Computing Architecture (ATCA™) standard as defined in the PICMG 3.0 AdvancedTCA specification. In another embodiment, computer system 100 and embedded computer chassis 101 may comply with CompactPCI standard. The embodiment of the invention is not limited to the use of these standards, and the use of other standards is within the scope of the invention.

Embedded computer chassis 101 may be comprised of at least three distinct sections: a computing module portion 105, a fan module portion 103 and an air plenum 107. Computing module portion 105 may include a plurality of slots for inserting computing modules 118, for example payload modules and switch modules. Computing modules 118 may couple to backplane (not shown for clarity) to facilitate power distribution and/or communication using a bus topology, switch fabric topology, and the like. In an embodiment, backplane may comprise for example and without limitation, 100-ohm differential signaling pairs. When in operation, computing modules 118 generate heat that must be removed from embedded computer chassis 101.

Computing modules 118 may comprise at least one switch module coupled to any number of payload modules via the backplane, which may accommodate any combination of a packet switched backplane including a distributed switched fabric, or a multi-drop bus type backplane. Backplanes architectures may include CompactPCI, Advanced Telecom Computing Architecture (AdvancedTCA), and the like.

Payload modules may add functionality to computer system 100 through the addition of processors, memory, storage devices, I/O elements, and the like. In other words, payload module may include any combination of processors, memory, storage devices, I/O elements, and the like, to give computer system 100 any functionality desired by a user.

In an embodiment, computer system 100 can use switch module as a central switching hub with any number of payload modules coupled to one or more switch modules. Computer system 100 may support a point-to-point, switched input/output (I/O) fabric. Computer system 100 may be implemented by using one or more of a plurality of switched fabric network standards, for example and without limitation, InfiniBand™, Serial RapidIO™, Ethernet™, AdvancedTCA™, PCI Express™, Gigabit Ethernet, and the like. Computer system 100 is not limited to the use of these switched fabric network standards and the use of any switched fabric network standard is within the scope of the invention.

In an embodiment, fan module portion 103 is adjacent to computing module portion 105. In a particular embodiment, and not limiting of the invention, fan module portion 103 is disposed above computing module portion 105. Fan module portion 103 may be a cavity housing a plurality of fan module bays 106, where each fan module bay 106 is disposed to accept a fan module 108 for drawing cooling air 120 through computing module portion 105. In an embodiment, each fan module 108 may include one or more fans, power and control circuitry, and the like. Fan modules 108 may plug into each fan module bay 106 and receive power from a central or dedicated power supply for embedded computer chassis 101.

In an embodiment, air plenum 107 is adjacent to computing module portion 105. In a particular embodiment, and not limiting of the invention, air plenum 107 is disposed below computing module portion 105. Air plenum 107 may include an entry screen/filter and a cavity where cooling air 120 enters embedded computer chassis 101 from a front side 102. This is not limiting of the invention, as cooling air 120 may enter air plenum 107 in locations in addition to or other than front side 102.

In an embodiment, embedded computer chassis 101 includes a fan module portion cover 110 rotatably mounted about a shaft 112 on front side of embedded computer chassis 101. Fan module portion cover 110 may be rotatable to an open position 130 away 122 and down 124 from fan module portion 103 on application of an opening force 134. Further, fan module portion cover 110 is elastically disposed via an elastic means 140 to automatically rotate to a closed position 132 up 128 and towards 126 fan module portion 103 in the absence of the opening force 134. Shaft 112 may include a portion of a hinge coupled to front side 102 and fan module portion cover 110 to secure fan module portion cover 110 to front side of embedded computer chassis 101 and provide a pivot point about which fan module portion cover 110 may rotate.

In an embodiment, opening force 134 may be a manual force exerted by maintenance personnel to open fan module portion cover 110 to access fan modules 108 for service or replacement. Opening force 134 may be manifested as a torque exerted at any location on fan module portion cover 110 to rotate to open position 130. Opening force 134 is not limited to the aforementioned embodiments, and may include any applied force or torque (manual or automatic) applied though manual or mechanical means to rotate fan module portion cover 110 to open position 130.

In an embodiment, elastic means 140 may include an elastic force 136 applied directly or via a torque to automatically rotate fan module portion cover 110 to closed position 132. Elastic means 140 may be manifested at any location on fan module portion cover 110 to automatically rotate fan module portion cover 110 to closed position 132 upon removal of opening force 134. In an embodiment, opening force 134 must be applied such that it overcomes elastic means 140, including elastic force 136, to rotate fan module portion cover 110 to open position 130.

In an embodiment, the closure rate 138 of fan module portion cover 110 may optionally be regulated as described in more detail below. In another embodiment, upon reaching closed position 132, a latching apparatus 114 may optionally be used to secure fan module portion cover 110 to fan module portion 103. Latching apparatus 114 may be, for example and without limitation, a threaded screw and threaded receiving portion, a one or two part clasp, a hook portion coupled to interface with a substantially cylindrical bar portion (i.e. lifting the fan module portion cover 110 to over the bar potion to engage a hook to secure in closed position 132), and the like. These embodiments are exemplary and not meant to be limiting of latching apparatus 114, as any means, mechanical, magnetic, electrical, the like may be used as latching apparatus 114 and be within the scope of the invention.

Although fan module portion cover 110 is shown in an obtuse “L” shape, this is not limiting of the invention. Fan module portion cover 110 may be “L” shaped, acute “L” shaped, flat, or have any other form factor to provide access to fan modules 108 and fan module portion 103.

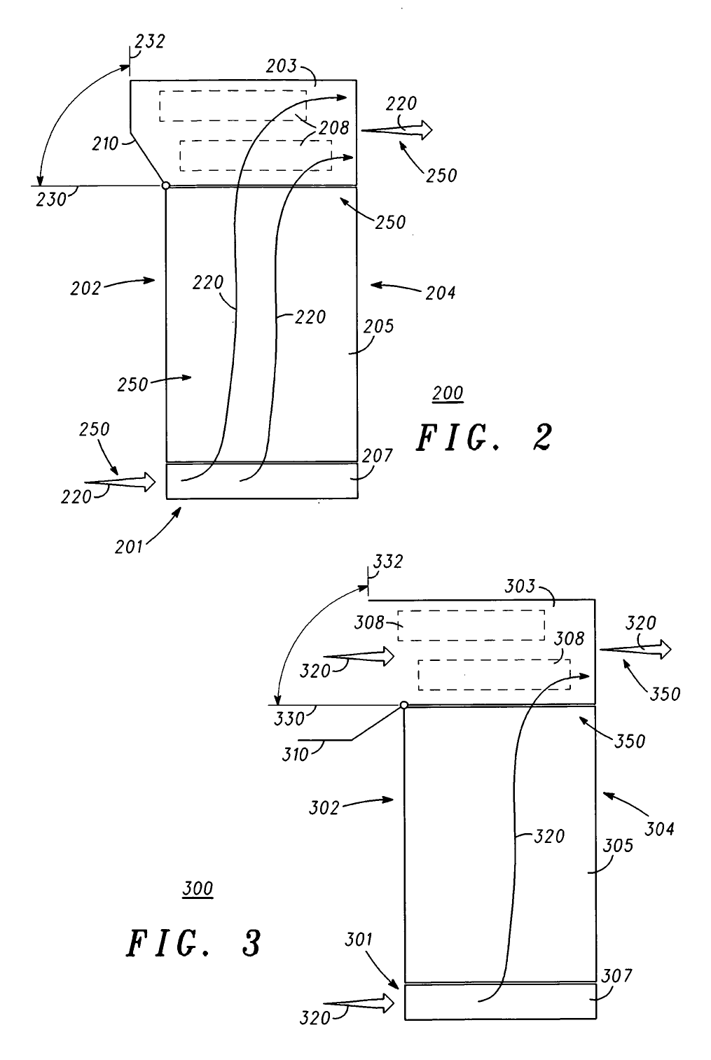

FIG. 2 representatively illustrates a cut-away elevation view of a computer system 200 in accordance with an exemplary embodiment of the present invention. As shown in FIG. 2, computer system 200 includes embedded computer chassis 201 having a front side 202 and a rear side 204. Embedded computer chassis 201 also may include fan module portion 203, computing module portion 205 and air plenum 207 substantially as described above.

Fan module portion 203 includes a plurality of fan modules 208 disposed to draw cooling air 220 into embedded computer chassis 201, through computing module portion 205 to cool computing modules. In the embodiment shown, fan module portion cover 210 is in closed position 232 as opposed to open position 230. Fan module portion cover 210 being in the closed position 232 allows cooling air 220 to flow substantially in a cooling air path 250 to substantially optimally cool computing modules in computing module portion 205.

As shown, but not limiting of the invention, cooling air 220 is drawn into embedded computer chassis 201 using plurality of fan modules 208 via air plenum 207 adjacent to computing module portion 205. In an embodiment, cooling air 220 is drawn in from front side 202 of embedded computer chassis 201 and passes through computing module portion 205, thereby cooling computing modules. Cooling air 220 is then exhausted from fan module portion 203 through rear side 204 of embedded computer chassis 201. In an embodiment, and not limiting of the invention, cooling air 220 entering front side 202 enters air plenum 207 substantially horizontally and perpendicular to front side 202. Further, cooling air 220 passes through computing module portion 205 substantially vertically and parallel to front side 202 and rear side 204. Still further, cooling air 220 then exhausts from fan module portion 203 substantially horizontally and perpendicular to rear side 204.

As shown and described, cooling air 220 forms a cooling air path 250 to cool computing modules in computing module portion 205. Cooling air path follows ambient, cooler air from one side of embedded computer chassis 201 (shown as front side 202), passes it through computing module portion 205, an exhausts the cooling air 220 (which has been heated due to heat removal from computing module portion 205) through an opposite side (shown as rear side 204) of embedded computer chassis 201. Maintaining cooling air path ensures components of computer system 200, particular those in computing module portion 205 do not overheat. If cooling air path 250 is interrupted and/or short-circuited, heat removal from computing module portion 205 may be hindered, thereby causing overheating of computer system 200.

Since cooling air 220 enters one side of embedded computer chassis 201 and exhausts from the other side, there is no short-circuiting of the cooling air 220. Short-circuiting may include a substantial portion of cooling air recently exhausted from embedded computer chassis 201 being immediately re-introduced as fresh cooling air at air plenum 207. Short-circuiting may also include cooling air 220 entering embedded computer chassis 201 at a location other than air plenum 207 and not passing through computing module portion 205, thereby not cooling computing modules. In either instance, adequate air at an adequately cool temperature may not be supplied, and computer system 200 may overheat.

FIG. 3 representatively illustrates a cut-away elevation view of a computer system in accordance with another exemplary embodiment of the present invention. As shown in FIG. 3, computer system 300 includes embedded computer chassis 301 having a front side 302 and a rear side 304. Embedded computer chassis 301 also may include fan module portion 303, computing module portion 305 and air plenum 307 substantially as described above.

Fan module portion 303 includes a plurality of fan modules 308 disposed to draw cooling air 320 into embedded computer chassis 301, through computing module portion 305 to cool computing modules. In the embodiment shown, fan module portion cover 310 is in open position 330 as opposed to closed position 332. Fan module portion cover 310 being in the open position 330 allows cooling air 320 to short-circuit (bypass) computing module portion 305 and thereby interrupt cooling air path 250. As shown with fan module portion cover 310 in open position 330, at least a portion of cooling air 320 bypasses air plenum 307 and computing module portion 305 to enter fan module portion 303 directly from front side 302 of embedded computer chassis 301. The interruption of cooling air path 250 causes inadequate cooling air 320 to pass through computing module portion 305, and thereby allow computing modules in computing module portion to overheat.

The embodiment shown in FIG. 3 may occur when service personnel rotate fan module portion cover 310 to open position 330 to access plurality of fan modules 308 for service or replacement. By having fan module portion cover 310 automatically return to closed position 332, cooling air path 250 may be maintained automatically without service personnel having to manually close fan module portion cover 310 or replace an access hatch. This ensures that adequate cooling air 320 reaches computing module portion 305 and prevents overheating of computer system 300.

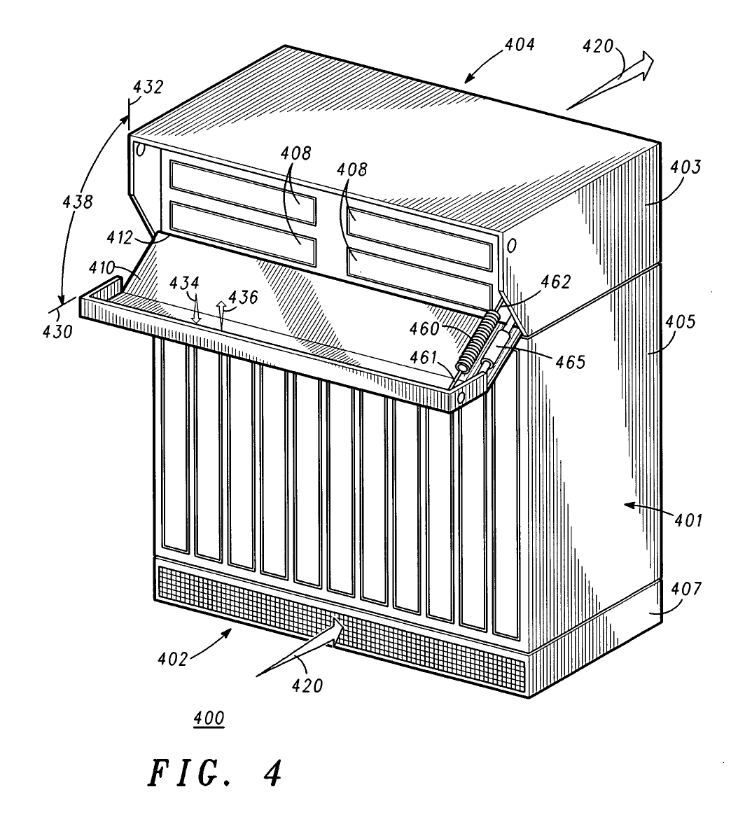

FIG. 4 representatively illustrates a computer system 400 in accordance with another exemplary embodiment of the present invention. As shown in FIG. 4, computer system 400 includes embedded computer chassis 401 having a front side 402 and a rear side 404. Embedded computer chassis 401 also may include fan module portion 403, computing module portion 405 and air plenum 407 substantially as described above.

In an embodiment, elastic means 140 may comprises a linear motion spring 460 with first end 461 coupled to fan module portion cover 410 and second end 462 coupled to fan module portion 403. Linear motion spring 460 may be a unitary body coiled spring with a spring constant chosen to meet a desired closure rate 438. Although only one linear motion spring 460 is shown, any number of linear motion springs 460 may be included (for example, one on each end of fan module portion cover 410) and be within the scope of the invention. Linear motion spring 460 may provide elastic force 436 necessary to automatically rotate fan module portion cover 410 about shaft 412 to closed position 432 from open position 430 upon removal of opening force 434. This allows cooling air 420 brought into embedded computer chassis 401 via fan modules 408 to follow cooling path 250 and adequately cool computing modules in computing module portion 405.

In an embodiment, closure rate 438 may be regulated through use of damper 465. Damper 465 may be a plunger-type shock absorber or any other friction producing device that regulates and/or slows closure rate 438 of fan module portion cover 410.

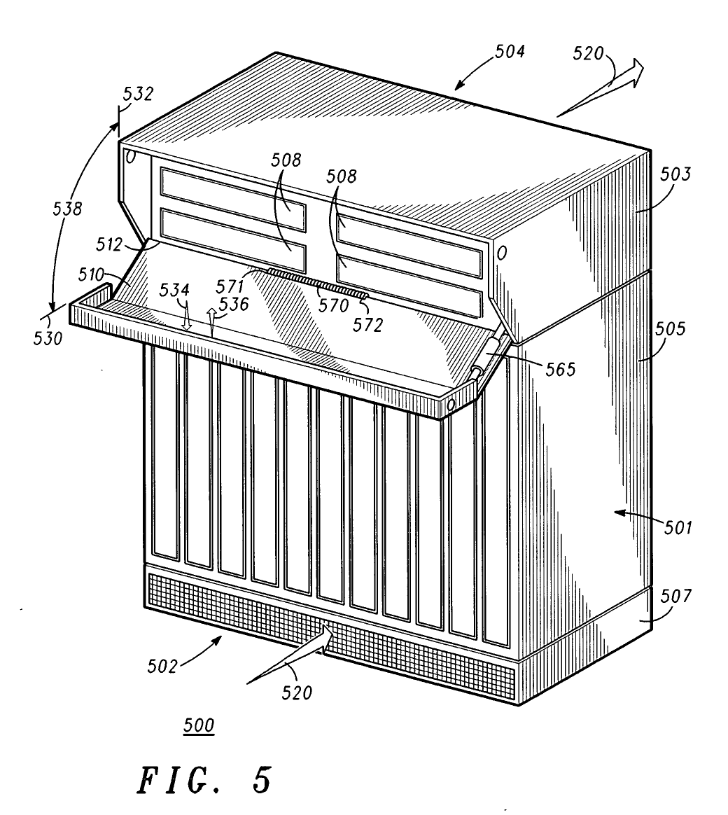

FIG. 5 representatively illustrates a computer system 500 in accordance with yet another exemplary embodiment of the present invention. As shown in FIG. 5, computer system 500 includes embedded computer chassis 501 having a front side 502 and a rear side 504. Embedded computer chassis 501 also may include fan module portion 503, computing module portion 505 and air plenum 507 substantially as described above.

In an embodiment, elastic means 140 may comprises one or more unitary variable torque spring 570 wrapped about shaft 512 and frictionally engaging at least one of fan module portion cover 510 and embedded computer chassis 501. Unitary variable torque spring 570 may have a first and second end to frictionally engage at a first location 571 and/or a second location 572 respectively. A spring constant may be chosen to meet a desired closure rate 538. In an embodiment, unitary variable torque spring 570 may include a unitary helical element wrapped around the outer diameter of shaft 512. The helical element may produce a variable torque as fan module portion cover 510 is rotated from closed position 532 to open position 530.

Although only one unitary variable torque spring 570 is shown, any number may be included and be within the scope of the invention. Unitary variable torque spring 570 may provide elastic force 536 necessary to automatically rotate fan module portion cover 510 about shaft 512 to closed position 532 from open position 530 upon removal of opening force 534. This allows cooling air 520 brought into embedded computer chassis 501 via fan modules 508 to follow cooling path 250 and adequately cool computing modules in computing module portion 505.

In an embodiment, closure rate 538 may be regulated through use of damper 565. Damper 565 may be a plunger-type shock absorber or any other friction producing device that regulates and/or slows closure rate 538 of fan module portion cover 510.

The embodiments depicted above for the elastic force are exemplary and not limiting of the invention. Other mechanisms of providing elastic means are within the scope of the invention.

The above embodiments offer the advantage of an unlimited service interval for maintenance personnel when servicing or changing a fan module. The above embodiments are applicable in any high-availability computer system where fans have a cavity to cool and maintenance requires opening the cavity, which allows cooling air to bypass the cavity intended for cooling. Further, the above embodiments offer the advantage of providing a hinged fan module portion cover that does not intrude on the physical space of another computer chassis above or below the embedded computer chassis. A fan module portion cover that opens up and allows gravity to rotate to the closed position without use of an elastic means will interfere with the physical space required of a computer chassis sitting directly above the embedded computer chassis.

In the foregoing specification, the invention has been described with reference to specific exemplary embodiments; however, it will be appreciated that various modifications and changes may be made without departing from the scope of the present invention as set forth in the claims below. The specification and figures are to be regarded in an illustrative manner, rather than a restrictive one and all such modifications are intended to be included within the scope of the present invention. Accordingly, the scope of the invention should be determined by the claims appended hereto and their legal equivalents rather than by merely the examples described above.

For example, the steps recited in any method or process claims may be executed in any order and are not limited to the specific order presented in the claims. Additionally, the components and/or elements recited in any apparatus claims may be assembled or otherwise operationally configured in a variety of permutations to produce substantially the same result as the present invention and are accordingly not limited to the specific configuration recited in the claims.

Benefits, other advantages and solutions to problems have been described above with regard to particular embodiments; however, any benefit, advantage, solution to problem or any element that may cause any particular benefit, advantage or solution to occur or to become more pronounced are not to be construed as critical, required or essential features or components of any or all the claims.

Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

We claim:

1. An embedded computer chassis having a front side and a rear side, the embedded computer chassis comprising:
a computing module portion;
a fan module portion disposed adjacent to the computing module portion;
a plurality of fan module bays in the fan module portion, wherein each of the plurality of fan module bays is coupled to accept a fan module for drawing cooling air though the computing module portion; and
a fan module portion cover rotatably mounted about a shaft on the front side of the embedded computer chassis, wherein the fan module portion cover is rotatable to an open position away and down from the fan module portion on application of an opening force, and wherein the fan module portion cover is elastically disposed to automatically rotate to a closed position up and towards the fan module portion in absence of the opening force.

2. The embedded computer chassis of claim 1, further comprising an air plenum disposed adjacent to the computing module portion, wherein the cooling air is drawn into the air plenum from the front side of the embedded computer chassis, wherein the cooling air passes through the computing module portion, and wherein the cooling air is exhausted from the fan module portion through the rear side of the embedded computer chassis.

3. The embedded computer chassis of claim 2, wherein the air plenum is disposed below the computing module portion.

4. The embedded computer chassis of claim 1, wherein the fan module portion is disposed above the computing module portion.

5. The embedded computer chassis of claim 1, further comprising an elastic means coupled to the fan module portion cover and the fan module portion to provide an elastic force to automatically rotate the fan module portion cover to the closed position in absence of the opening force.

6. The embedded computer chassis of claim 5, wherein the elastic means comprises a linear motion spring with a first end coupled to the fan module portion cover and a second end coupled to the fan module portion.

7. The embedded computer chassis of claim 5, wherein the elastic means comprises a unitary variable torque spring wrapped about the shaft and frictionally engaging at least one of the fan module portion cover and the fan module portion.

8. The embedded computer chassis of claim 1, wherein when the fan module portion cover is in the closed position, the fan module portion cover secures to the fan module portion via at least one latching apparatus.

9. The embedded computer chassis of claim 1, further comprising a damper, wherein the damper regulates a closure rate when the fan module portion cover transitions from the open position to the closed position.

10. A method of maintaining a cooling air path in an embedded computer chassis having a front side and a rear side, the method comprising:
providing a computing module portion;
providing a fan module portion disposed adjacent to the computing module portion and coupled to accept a plurality of fan modules for drawing cooling air though the computing module portion;
drawing cooling air into the front side of the embedded computer chassis through an air plenum disposed adjacent to the computing module portion, wherein the cooling air passes through the computing module portion, and wherein the cooling air is exhausted from the fan module portion through a rear side of the embedded computer chassis, thereby defining the cooling air path;
applying an opening force to a fan module portion cover to place the fan module portion cover in an open position, wherein the fan module portion cover is rotatable to the open position away and down from the fan module portion, wherein while in the open position the cooling air path is substantially interrupted; and
upon release of the opening force, an elastic means automatically rotating the fan module portion cover to a closed position up and towards the fan module portion, thereby maintaining the cooling air path.

11. The method of claim 10, wherein the elastic means comprises a linear motion spring with a first end coupled to the fan module portion cover and a second end coupled to the fan module portion.

12. The method of claim 10, wherein the elastic means comprises a unitary variable torque spring wrapped about a shaft and frictionally engaging at least one of the fan module portion cover and the fan module portion.

13. The method of claim 10, wherein when the fan module portion cover is in the closed position, securing the fan module portion cover to the fan module portion via at least one latching apparatus.

14. The method of claim 10, further comprising regulating a closure rate of the fan module portion cover via a damper.

15. The method of claim 10, wherein the cooling air entering the front side substantially horizontally and perpendicular to the front side.

16. The method of claim 10, wherein the cooling air passing through the computing module portion substantially vertically.

17. The method of claim 10, wherein the cooling air exhausting from the fan module portion substantially horizontally and perpendicular to the rear side.

18. The method of claim 10, wherein the air plenum is disposed below the computing module portion.

19. The method of claim 10, wherein the fan module portion is disposed above the computing module portion.

20. The method of claim 10, wherein interrupting the cooling air path comprises substantially short-circuiting the cooling air path.
